(19) United States
(12) Patent Application Publication
(10) Pub. No.: US 2016/0190334 A1
(43) Pub. Date: Jun. 30, 2016

(54) MEMORY DEVICE AND METHOD OF MANUFACTURING THE SAME

(71) Applicant: MACRONIX International Co., Ltd., Hsinchu (TW)

(72) Inventors: Hong-Ji Lee, Hsinchu (TW); Han-Hui Hsu, Hsinchu (TW)

(21) Appl. No.: 14/582,929

(22) Filed: Dec. 24, 2014

(51) Int. Cl. H01L 29/788; H01L 21/28; H01L 21/3213; H01L 29/06; H01L 27/115; H01L 21/311

(52) U.S. Cl. CPC H01L 29/7883; H01L 27/11521; H01L 21/31116; H01L 21/32135; H01L 21/32139; H01L 29/0649; H01L 21/28273

(57) ABSTRACT

Provided is a memory device including a substrate, a plurality of tunneling dielectric layers, a plurality of isolation structures, and a plurality of cap layers. The tunneling dielectric layers are located on the substrate. Each isolation structure has an upper portion and a lower portion. The lower portions of the isolation structures are located in the substrate and arranged alternately with the tunneling dielectric layers along a first direction. The upper portions of the isolation structures are located on the lower portions. The cap layers are located on the upper portions. A top surface of the cap layer is a planar surface.

### BACKGROUND OF THE INVENTION

1. [Field of the Invention]

The invention relates to a semiconductor device and a method of manufacturing the same, and more particularly relates to a memory device and a method of manufacturing the same.

2. [Description of Related Art]

Generally, the manufacturing process of a memory device faces problems, such as junction leakage and floating gate short. Junction leakage results from damaging of the tunneling dielectric layer during a plasma etching process; and floating gate short is caused by residual gate material between adjacent floating gates, which is generated when patterning the word lines. However, if over-etching is applied to completely remove the gate material between adjacent floating gates, the tunneling dielectric layer may be damaged and the risk of junction leakage may increase. Therefore, junction leakage and floating gate short are in a trade-off relationship, and they both significantly influence the yield rate and the reliability of the product.

### SUMMARY OF THE INVENTION

The invention provides a memory device and a method of manufacturing the same for solving the problems of junction leakage and floating gate short and thereby improving the yield rate and reliability of a product.

The invention provides a memory device including a substrate, a plurality of tunneling dielectric layers, a plurality of isolation structures, and a plurality of cap layers. The substrate includes a plurality of first regions and a plurality of second regions, wherein the first regions and the second regions extend in a first direction and are arranged alternately in a second direction. The tunneling dielectric layers are disposed on the substrate and extend in the second direction across the first regions and the second regions. The isolation structures each have an upper portion and a lower portion, wherein the lower portions of the isolation structures are located in the substrate and arranged alternately with the tunneling dielectric layers in the first direction, and the upper portions of the isolation structures are disposed on the lower portions. The cap layers are disposed on the upper portions of the isolation structures, wherein a top surface of each of the cap layers is a planar surface.

In an embodiment of the invention, a top surface of the upper portion of each of the isolation structures is higher than a top surface of each of the tunneling dielectric layers, and a bottom surface of the upper portion of each of the isolation structures is level with the top surface of each of the tunneling dielectric layers.

In an embodiment of the invention, the memory device further includes a plurality of first conductor layers disposed on the tunneling dielectric layers of the second regions, a dielectric layer covering the first conductor layers, and a second conductor layer disposed on the dielectric layer and including a body portion and a plurality of extending portions, wherein the extending portions and the first conductor layers are arranged alternately in the first direction.

In an embodiment of the invention, a structure of the upper portion of each of the isolation structures and the cap layer on the upper portion satisfies the following (1) and (2):

b≦a<c, and (1)

b≧⅓ a, (2)

wherein a represents a width of a bottom portion of each of the extending portions of the second conductor layer, b represents a width of the top surface of each of the cap layers, and c represents a width of the bottom surface of the upper portion of each of the isolation structures.

In an embodiment of the invention, an included angle between a sidewall of the upper portion and the bottom surface of the upper portion of each of the isolation structures is in a range of 40 degrees to 87 degrees.

In an embodiment of the invention, a material of the cap layer includes a high dielectric constant material or a combination of the high dielectric constant material and a low dielectric constant material.

The invention further provides a memory device including a substrate, a plurality of tunneling dielectric layers, a plurality of isolation structures, and a plurality of cap layers. The tunneling dielectric layers are disposed on the substrate. The isolation structures each have an upper portion and a lower portion, wherein the lower portions of the isolation structures are located in the substrate and arranged alternately with the tunneling dielectric layers in a first direction, and the upper portions of the isolation structures are disposed on the lower portions. The cap layers are disposed on the upper portions of the isolation structures, wherein a top surface of each of the cap layers is a planar surface.

In an embodiment of the invention, a top surface of the upper portion of each of the isolation structures is higher than a top surface of each of the tunneling dielectric layers, and a bottom surface of the upper portion of each of the isolation structures is level with the top surface of each of the tunneling dielectric layers.

In an embodiment of the invention, a structure of the upper portion of each of the isolation structures and the cap layer on the upper portion satisfies the following (1) and (2):

$$\begin{matrix}b \geq c - 2 \times T 1 < c , and & ( 1 ) \\ b \geq \frac{c - 2 \times T 1}{3} , & ( 2 )\end{matrix}$$

wherein T1 represents a thickness of the cap layer, b represents a width of the top surface of each of the cap layers, and c represents a width of the bottom surface of the upper portion of each of the isolation structures.

In an embodiment of the invention, an included angle between a sidewall of the upper portion and the bottom surface of the upper portion of each of the isolation structures is in a range of 40 degrees to 87 degrees.

The invention further provides a manufacturing method for manufacturing a memory device. The manufacturing method includes the following: a plurality of stack layers are formed on a substrate. Each of the stack layers includes a tunneling dielectric layer and a first conductor layer, and the first conductor layer is disposed on the tunneling dielectric layer. A plurality of isolation structures are formed in the stack layers and the substrate. A portion of the isolation structures is removed with the stack layers as a mask to form a plurality of openings in the stack layers. A bottom surface of each of the openings is higher than a top surface of the tunneling dielectric layer. A dielectric layer conformally is formed on the isolation structures and the stack layers. A second conductor layer is formed on the isolation structures. A portion of the dielectric layer is removed with the second conductor layer as a mask to from a cap layer and expose a surface of the first conductor layer. The first conductor layer and the second conductor layer are removed to expose the top surface of the tunneling dielectric layer.

In an embodiment of the invention, a thickness of the second conductor layer remain in the openings is in a range of 30 nm to 45 nm.

In an embodiment of the invention, an etching selectivity between the dielectric layer and the first conductor layer, and an etching selectivity between the dielectric layer and the second conductor layer in the step of removing the portion of the dielectric layer are 1 to 15.

In an embodiment of the invention, a material of the dielectric layer includes a high dielectric constant material or a combination of the high dielectric constant material and a low dielectric constant material.

In an embodiment of the invention, if the material of the dielectric layer is the combination of the high dielectric constant material and the low dielectric constant material, an etching gas for removing the portion of the dielectric layer includes CF₄, CHF₃, O₂ and He.

In an embodiment of the invention, the step of removing the portion of the dielectric layer includes removing the portion of the dielectric layer between the first conductor layer and the second conductor layer.

In an embodiment of the invention, if the material of the dielectric layer is the combination of the high dielectric constant material and the low dielectric constant material, an etching gas for removing the dielectric layer between the first conductor layer and the second conductor layer includes CF₄, CH₂F₂, CHF₃, CH₃F, CH₄, O₂, and He.

In an embodiment of the invention, the first conductor layer includes one, two, or more conductor material layers, and the two or more conductor material layers include the same or different conductor materials.

In an embodiment of the invention, the step of forming the second conductor layer in the openings includes: forming a conductor material layer on the substrate to fill the conductor material layer in the openings; forming a patterned mask layer on the conductor material layer; and removing a portion of the conductor material layer with the patterned mask layer as a mask to expose the dielectric layer on the stack layers.

In an embodiment of the invention, a material of the patterned mask layer includes: SiON, a carbonaceous material, an oxide, amorphous silicon, a nitride, polysilicon, or a combination thereof.

Based on the above, according to the invention, the second conductor layer on the isolation structure is used as the mask layer to remove a portion of the dielectric layer, so as to prevent the over-etching process from causing damage to the tunneling dielectric layer. In addition, the invention utilizes the high etching selectivity between the dielectric layer and the first conductor layer, and the high etching selectivity between the dielectric layer and the second conductor layer to completely remove the first conductor layer between the isolation structures, so as to avoid floating gate short. Thus, the memory device and the manufacturing method provided by the invention effectively solve the problems of junction leakage and floating gate short and thereby improve the yield rate and reliability of the product.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1A to FIG. 1G are schematic perspective views showing a method of manufacturing a memory device according to an embodiment of the invention.

FIG. 2 is an enlarged view of a portion P of FIG. 1G.

FIG. 3 is a schematic perspective view showing a memory device according to another embodiment of the invention.

### DESCRIPTION OF THE EMBODIMENTS

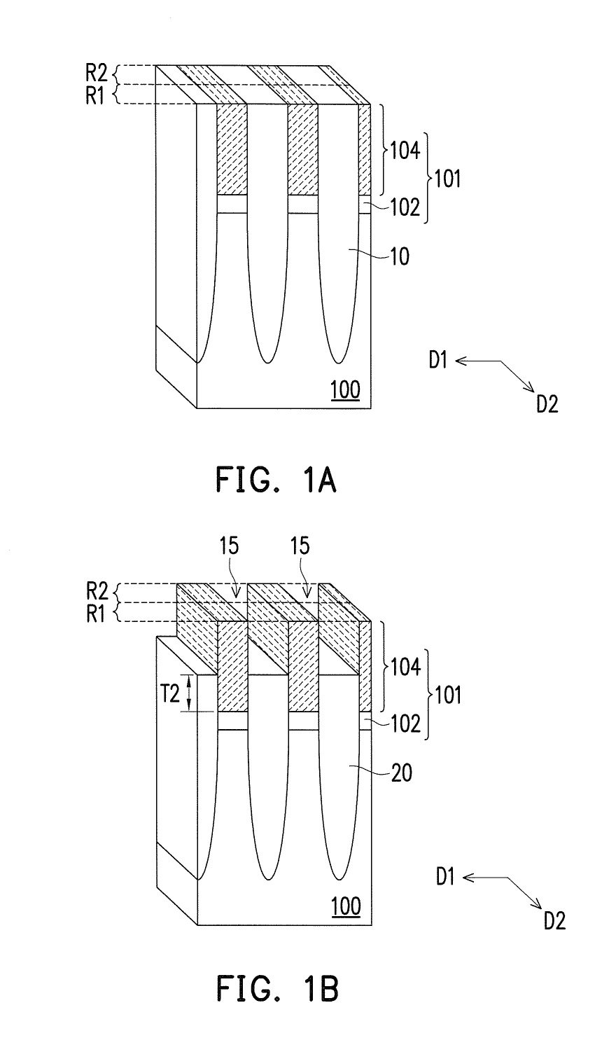

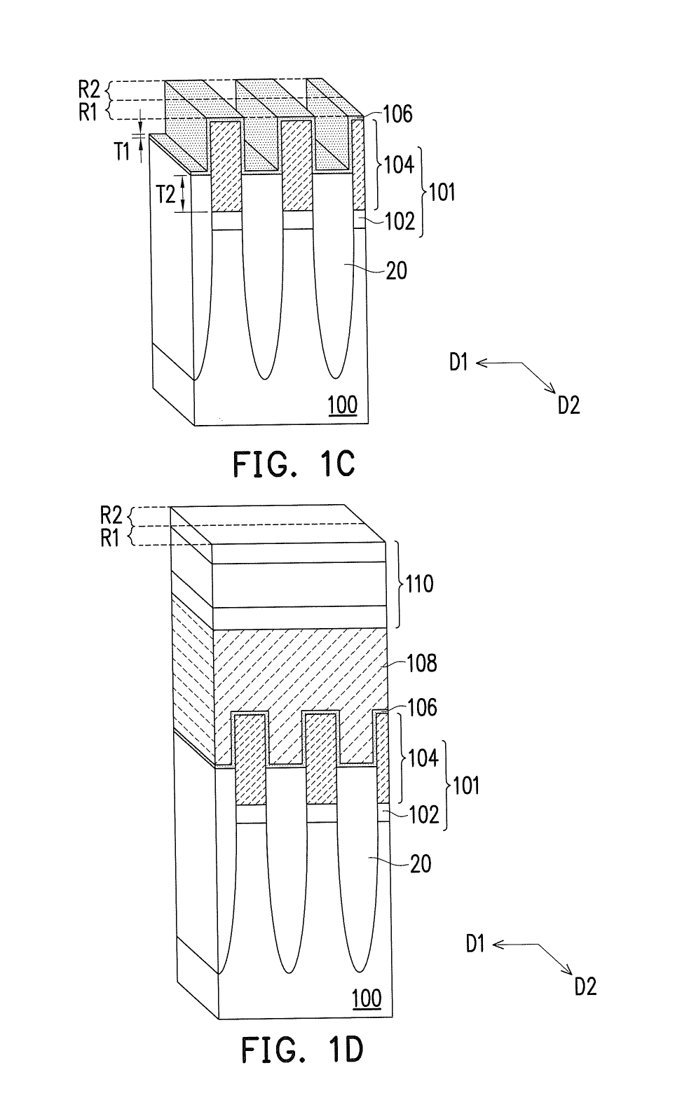

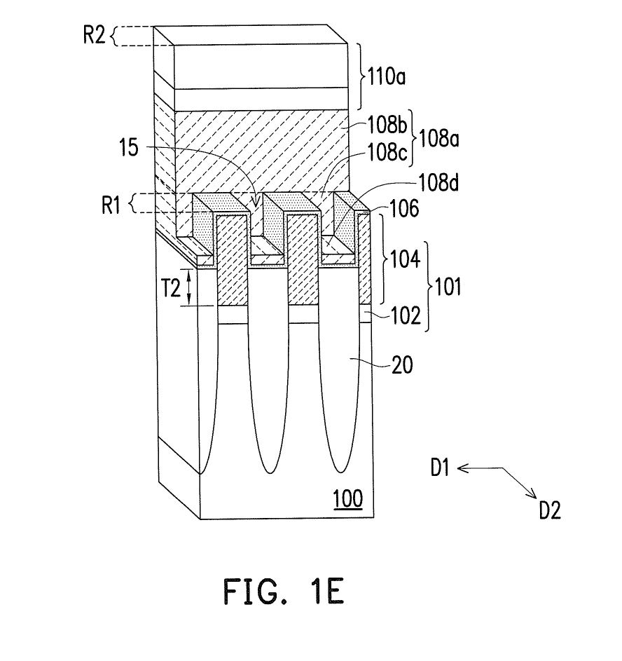

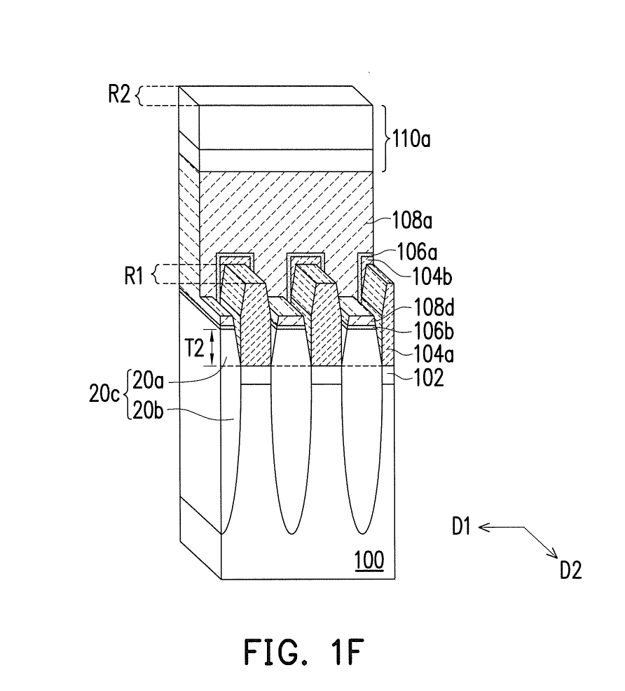

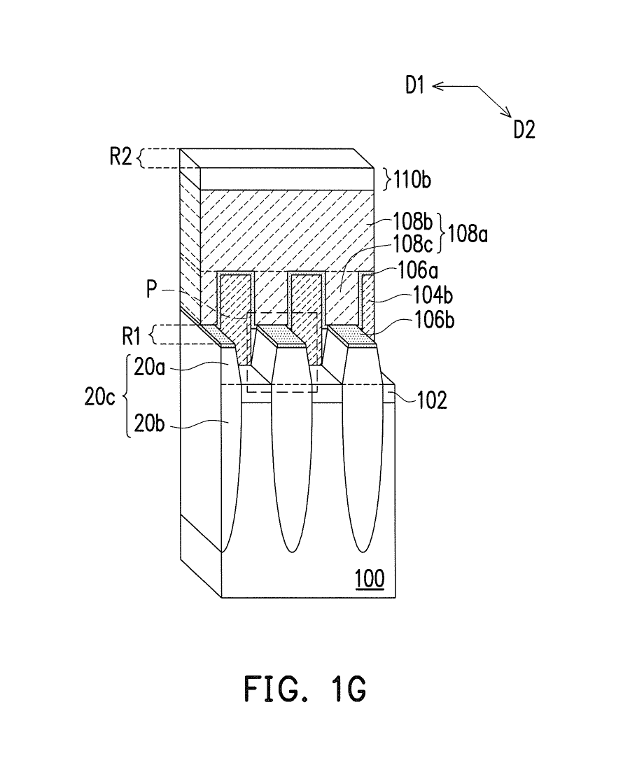

FIG. 1A to FIG. 1G are schematic perspective views showing a method of manufacturing a memory device according to an embodiment of the invention.

With reference to FIG. 1A, the invention provides a method of manufacturing a memory device, including the following steps. First, a substrate 100 is provided. The substrate 100 includes a plurality of first regions R1 and a plurality of second regions R2. The first regions R1 and the second regions R2 extend in a first direction D1 and are arranged alternately in a second direction D2. Although FIG. 1A illustrates only one first region R1 and one second region R2, the invention is not limited thereto. The disclosure of FIG. 1A may represent more than one first region R1 and more than one second region R2. The same applies to the other figures mentioned hereinafter. The substrate 100 is a semiconductor substrate, a semiconductor compound substrate, or a semiconductor over insulator (SOI) substrate, for example. The semiconductor is IVA group atoms, such as silicon or germanium, for example. The semiconductor compound is formed of IVA group atoms, such as silicon carbide or silicon germanium, or formed of IIIA group atoms and VA group atoms, such as gallium arsenide, for example.

Then, a plurality of stack layers 101 are formed on the substrate 100, and a plurality of isolation structures 10 are formed in the stack layers 101 and the substrate 100. Each of the stack layers 101 includes a tunneling dielectric layer 102 and a first conductor layer 104. As shown in FIG. 1A, the first conductor layer 104 is disposed on the tunneling dielectric layer 102. A material of the tunneling dielectric layer 102 is silicon oxide, and a method of forming the tunneling dielectric layer 102 may include performing chemical vapor deposition or thermal oxidation. In an embodiment, the thickness of the tunneling dielectric layer 102 is in a range of 50 to 150 angstroms, for example. A material of the first conductor layer 104 may be doped polysilicon, undoped polysilicon, or a combination thereof, for example, and a method of forming the first conductor layer 104 may include performing chemical vapor deposition. In an embodiment, the first conductor layer 104 may include one, two, or more conductor material layers, for example. The aforementioned two or more conductor material layers may be the same conductor material or different conductor materials, for example. The thickness of the first conductor layer 104 is in a range of 500 to 1200 angstroms, for example. The isolation structures 10 and the stack layers 101 are arranged alternately in the first direction D1. A material of the isolation structure 10 is doped or undoped silicon oxide, high-density plasma oxide, silicon oxynitride, spin-on silicon oxide, low-k dielectric or a combination thereof, for example. The isolation structure 10 is a shallow trench isolation structure, for example.

In an embodiment, the method of forming a plurality of stack layers 101 on the substrate 100 and forming a plurality of isolation structures 10 in the stack layers 101 and the substrate 100 may include first forming a stack material layer (not shown) and a patterned mask layer (not shown) on the substrate 100, and then patterning the stack material layer by a dry etching process, e.g., reactive ion etching (RIE), to form the stack layers 101 and form a plurality of trenches (not shown) in the substrate 100. Next, a high-density plasma oxide layer is formed on the substrate 100 to fill the trenches. Thereafter, the high-density plasma oxide layer on the substrate 100 is planarized by chemical mechanical polishing (CMP) to expose a top surface of the first conductor layer 104 of the stack layers 101.

With reference to FIG. 1B, a portion of the isolation structure 10 is removed with the stack layers 101 as a mask, so as to form an opening 15 between adjacent two stack layers 101, and remain a plurality of isolation structure 20. In this embodiment, process conditions of this step may be controlled such that a bottom surface of the opening 15 is higher than a top surface of the tunneling dielectric layer 102, and a thickness T2 from a top surface of an isolation structure 20 to the top surface of the tunneling dielectric layer 102 is in a range of 15 nm to 40 nm.

With reference to FIG. 1C, a dielectric layer 106 is formed conformally on the isolation structures 20 and the stack layers 101. The dielectric layer 106 may have a single-layer structure. A material of the single-layer structure is a high dielectric constant material, for example. The high dielectric constant material is a dielectric material having a dielectric constant greater than 4, such as HfO₂, Al₂O₃, HfAlO or SiN. The dielectric layer 106 may also have a multi-layer structure. The multi-layer structure is a combination of a high dielectric constant material and a low dielectric constant material, such as a stack structure of oxide layer/nitride layer/oxide layer (ONO), oxide layer/nitride layer/oxide layer/nitride layer/oxide layer (O(NO)ₓNO; x is integers greater than 1). A method of forming the single-layer structure and the multi-layer structure may include performing chemical vapor deposition, thermal oxidation, or a combination thereof. In an embodiment, a thickness T1 of the dielectric layer 106 is in a range of 8 nm to 20 nm.

With reference to FIG. 1D, a second conductor layer 108 and a mask layer 110 are formed sequentially on the dielectric layer 106. A material of the second conductor layer 108 may be doped polysilicon, undoped polysilicon, or a combination thereof, for example, and a method of forming the second conductor layer 108 may include performing chemical vapor deposition. The mask layer 110 may be a single layer or a composite layer, such as SiON, a carbonaceous material, an oxide, amorphous silicon, a nitride, polysilicon, or a combination thereof. The carbonaceous material is amorphous carbon (a-C) or carbon-doped spin-on resist, for example. For example, the mask layer 110 may be a composite layer including silicon oxynitride, a-C, and silicon oxide in sequence. However, it should be noted that the invention is not limited thereto.

With reference to FIGS. 1D and 1E, then, the mask layer 110 and the second conductor layer 108 are patterned to form a patterned mask layer 110a and a patterned second conductor layer 108a and expose a top surface of the dielectric layer 106 of the first region R1. The second conductor layer 108a includes a body portion 108b and an extending portion 108c. The extending portion 108c is connected with the body portion 108b and is located in the opening 15 of the second region R2. Moreover, the extending portion 108c and the first conductor layer 104 are arranged alternately in the first direction D1. A second conductor layer 108d remains in each opening 15 of the first region R1. The second conductor layer 108d covers the dielectric layer 106, and a top surface of the second conductor layer 108d is lower than a top surface of the stack layers 101. In this embodiment, the thickness of the second conductor layer 108d is 30 nm to 45 nm. Nevertheless, the invention is not limited thereto. In other embodiments, the second conductor layer 108d may have any thickness as long as the thickness is sufficient to resist the subsequent etching processes and prevent the isolation structure 20 below from being etched. Accordingly, the second conductor layer 108d protects the tunneling dielectric layer 102 below and prevents an interface between the isolation structure 20 and the tunneling dielectric layer 102 from damage. In addition, in this embodiment, the second conductor layer 108a of the first region R1 serves as a control gate or a word line (WL), for example.

With reference to FIGS. 1E and 1F, a portion of the dielectric layer 106 is removed by performing an etching process with the second conductor layer 108d as a mask, so as to faun a dielectric layer 106a in the second region R2, form a cap layer 106b in the first region R1, and expose a surface of a first conductor layer 104a. In this embodiment, if the material of the dielectric layer 106 is a combination of a high dielectric constant material and a low dielectric constant material, such as oxide layer/nitride layer/oxide layer (ONO), an etching gas for removing the portion of the dielectric layer 106 may be CF₄, CHF₃, O₂, and He; and an etching gas for removing the portion of the dielectric layer 106 between the first conductor layer 104a and the second conductor layer 108d may be CF₄, CH₂F₂, CHF₃, CH₃F, CH₄, O₂, and He, for example. In an embodiment, in the etching process, an etching selectivity between the dielectric layer 106 and the first conductor layer 104a and an etching selectivity between the dielectric layer 106 and the second conductor layer 108d are 1-15, and thus the dielectric layer 106 on the stack layers 101 of the first region R1 is completely removed. Although the etching of the dielectric layer 106 to the first conductor layer 104a is high, a small portion of the first conductor layer 104a may still be removed, and thus a shape of the first conductor layer 104a may change slightly (as shown in FIG. 1F). Nevertheless, the change of the shape of the first conductor layer 104a does not affect the subsequent processes and operation of the memory device thereof. Moreover, in the etching process, the dielectric layer 106 on a sidewall of the second conductor layer 108d and a portion of the isolation structure 20 below are also removed, and the cap layer 106b and an isolation structure 20c remain in the first region R1. Therefore, an upper portion 20a of the isolation structure 20c has a little slope, which affects the subsequent effective field oxide height (EFH) and shape. Details thereof will be described later.

With reference to FIGS. 1F and 1G, the first conductor layer 104a on the tunneling dielectric layer 102 and the second conductor layer 108b on the cap layer 106b of the first region R1 are removed to expose a top surface of the tunneling dielectric layer 102. Because of the high etching selectivity between the first conductor layer 104a and the high etching selectivity between the second conductor layer 108d and the cap layer 106b, in the process of removing the second conductor layer 108d and the first conductor layer 104a, the cap layer 106b protects the isolation structure 20c below to prevent the interface between the isolation structure 20c and the tunneling dielectric layer 102 from being damaged. Accordingly, the problems of junction leakage and floating gate short are solved to improve the yield rate and reliability of the product. Furthermore, because the cap layer 106b of the first region R1 protects the isolation structure 20c below from damage, the top surfaces of the isolation structure 20c and the cap layer 106b are a planar surface. In addition, in the step of removing the first conductor layer 104a and the second conductor layer 108d, a portion of the patterned mask layer 110a may be removed to remain the patterned mask layer 110b.

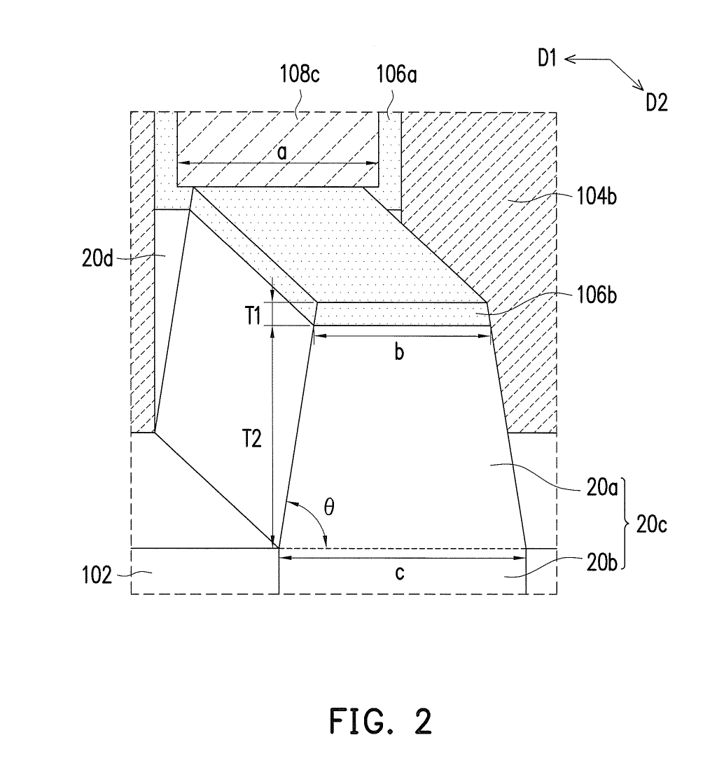

With reference to FIG. 1G and FIG. 2, the invention provides a memory device that includes: the substrate 100, a plurality of tunneling dielectric layers 102, a plurality of isolation structures 20c, a plurality of first conductor layers 104b, the dielectric layer 106a, the cap layer 106b, and the second conductor layer 108a. The substrate 100 includes a plurality of first regions R1 and a plurality of second regions R2. The first regions R1 and the second regions R2 extend in the first direction D1 and are arranged alternately in the second direction D2. The tunneling dielectric layers 102 are disposed on the substrate 100. The tunneling dielectric layers 102 extend in the second direction D2 across the first regions R1 and the second regions R2. Each of the isolation structures 20c has the upper portion 20a and the lower portion 20b. The upper portion 20a of the isolation structure 20c is located on the lower portion 20b, and the bottom surface of the upper portion 20a is level with the top surface of each of the tunneling dielectric layers 102. The lower portions 20b of the isolation structures 20c are located in the substrate 100 and arranged alternately with the tunneling dielectric layers 102 in the first direction D1. The cap layers 106b are located on the upper portions 20a of the isolation structures 20c. The top surface of the cap layer 106b is a planar surface. The first conductor layer 104b (serves as a floating gate, for example) is located on the tunneling dielectric layer 102 in the second region R2. The dielectric layer 106a covers the first conductor layer 104b and is disposed between the first conductor layer 104b and the second conductor layer 108a. In this embodiment, the dielectric layer 106a may serve as an inter-gate dielectric layer to electrically isolate the first conductor layer 104b and the second conductor layer 108c. The second conductor layer 108a (serves as a control gate or a word line, for example) is disposed on the dielectric layer 106a. The second conductor layer 108a includes the body portion 108b and a plurality of extending portions 108c. The extending portions 108c are connected with the body portion 108b and extend between two first conductor layers 104b. In other words, the extending portions 108c and the first conductor layers 104b are arranged alternately in the first direction D1. Moreover, as shown in FIG. 2, the memory device of this embodiment includes an isolation structure 20d located between the extending portions 108c and the substrate 100 of the second region R2. Because the isolation structure 20d is covered by the dielectric layer 106a and the extending portions 108c, when the etching process is performed, the isolation structure 20d can not be damaged. Therefore, the isolation structure 20d and the isolation structure 20c have different shapes. In this embodiment, the isolation structure 20d is substantially a rectangular body.

Moreover, in this embodiment, the upper portion 20a of each of the isolation structures 20c is covered by the cap layer 106b, and a double-layer structure consisting of the upper portion 20a and the cap layer 106b on the upper portion 20a is a trapezoid body having a structure that satisfies the following (1) and (2):

b≦a<c, (1)

b≧⅓ a, (2)

wherein a represents a width of a bottom portion of each extending portion 108c of the second conductor layer 108a.

b represents a width of the top surface of each cap layer 106b.

c represents a width of the bottom surface of the upper portion 20a of each isolation structure 20c.

Moreover, in an embodiment, an included angle θ between the sidewall of the upper portion 20a and the bottom surface of the upper portion 20a of each isolation structure 20c is in a range of 40 degrees to 87 degrees for example. In this embodiment, the upper portion 20a of each isolation structure 20c may be a trapezoid body. Therefore, the included angle θ is 40 degrees to 87 degrees, for example.

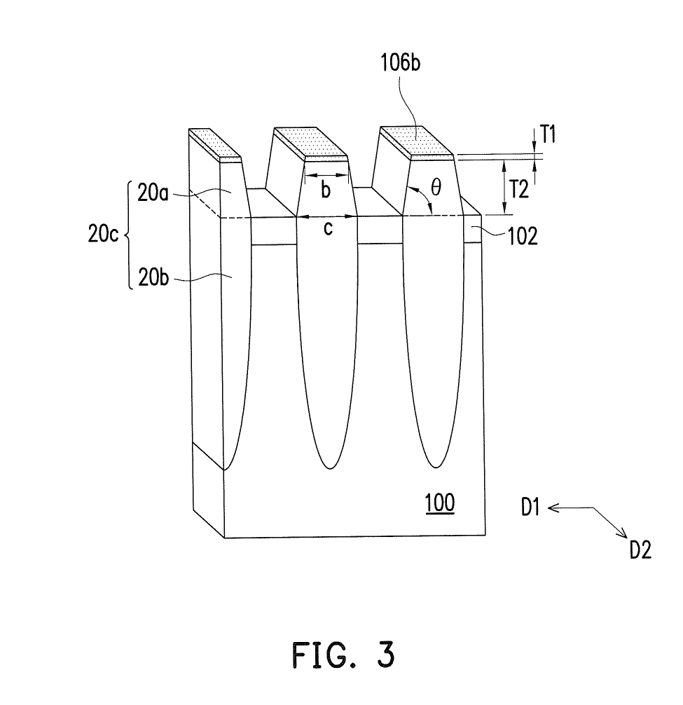

FIG. 3 is a schematic perspective view showing a memory device according to another embodiment of the invention.

With reference to FIG. 3, the invention further provides a memory device that includes the substrate 100, a plurality of tunneling dielectric layers 102, a plurality of isolation structures 20c, and the cap layer 106b. The tunneling dielectric layers 102 are disposed on the substrate 100. Each of the isolation structures 20c has the upper portion 20a and the lower portion 20b. The upper portion 20a of the isolation structure 20c is located on the lower portion 20b, and the bottom surface of the upper portion 20a is level with the top surface of each of the tunneling dielectric layers 102. The lower portions 20b of the isolation structures 20c are located in the substrate 100 and arranged alternately with the tunneling dielectric layers 102 in the first direction D1. The cap layers 106b are located on the upper portions 20a of the isolation structures 20c. The top surface of the cap layer 106b is a planar surface.

In this embodiment, the upper portion 20a of each isolation structure 20c is covered by the cap layer 106b, and a double-layer structure of the upper portion 20a and the cap layer 106b on the upper portion 20a is a trapezoid body having a structure that satisfies the following (3) and (4):

$$\begin{matrix}b \leq c - 2 \times T 1 < c , & ( 3 ) \\ b \geq \frac{c - 2 \times T 1}{3} , & ( 4 )\end{matrix}$$

wherein b represents the width of the top surface of each cap layer 106b.

c represents the width of the bottom surface of the upper portion 20a of each isolation structure 20c.

T1 represents a thickness of the cap layer 106b.

Moreover, the included angle θ between the sidewall of the upper portion 20a and the bottom surface of the upper portion 20a of each isolation structure 20c is in a range of 40 degrees to 87 degrees, for example. In this embodiment, the upper portion 20a of each isolation structure 20c may be a trapezoid body. Therefore, the included angle θ is 40 degrees to 87 degrees for example.

To sum up, according to the invention, the second conductor layer remained on the isolation structure is used as the mask layer when the dielectric layer on the stack layers of the first region is removed, and thus the isolation structure is protected. In addition, since the isolation structure is covered by the cap layer thereon, when the first conductor layer on the tunneling dielectric layer and the second conductor layer on the isolation structure are removed, the isolation structure is protected by the cap layer. Thus, the isolation structure is prevented form being over-etched and the thus isolation structure can provide the effective field oxide height (EFH), and the interface between the isolation structure and the tunneling dielectric layer can be protected from damage. In addition, the invention utilizes the high etching selectivity between the dielectric layer and the first conductor layer and the high etching selectivity between the dielectric layer and the second conductor layer to completely remove the first conductor layer between the isolation structures and the second conductor layer on the isolation structure, thereby avoiding floating gate short. Thus, the memory device and the manufacturing method thereof provided by the invention effectively solve the problems of junction leakage and floating gate short and improve the yield rate and reliability of the product.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

1. A memory device, comprising:
a substrate comprising a plurality of first regions and a plurality of second regions, wherein the first regions and the second regions extend in a first direction and are arranged alternately in a second direction;
a plurality of tunneling dielectric layers disposed on the substrate and extending in the second direction across the first regions and the second regions;
a plurality of isolation structures each comprising an upper portion and a lower portion, wherein the lower portions of the isolation structures are located in the substrate and arranged alternately with the tunneling dielectric layers in the first direction, and the upper portions of the isolation structures are disposed on the lower portions; and
a plurality of cap layers disposed on the upper portions of the isolation structures, wherein a top surface of each of the cap layers is a planar surface.

2. The memory device according to claim 1, wherein a top surface of the upper portion of each of the isolation structures is higher than a top surface of each of the tunneling dielectric layers, and a bottom surface of the upper portion of each of the isolation structures is level with the top surface of each of the tunneling dielectric layers.

3. The memory device according to claim 1, further comprising:
a plurality of first conductor layers disposed on the tunneling dielectric layers of the second regions;
a dielectric layer covering the first conductor layers; and
a second conductor layer disposed on the dielectric layer and comprising a body portion and a plurality of extending portions, wherein the extending portions and the first conductor layers are arranged alternately in the first direction.

4. The memory device according to claim 3, wherein a structure of the upper portion of each of the isolation structures and the cap layer on the upper portion satisfies the following (1) and (2):
b≦a<c, and (1)
b≧⅓ a, (2)
wherein a represents a width of a bottom portion of each of the extending portions of the second conductor layer, b represents a width of the top surface of each of the cap layers, and c represents a width of the bottom surface of the upper portion of each of the isolation structures.

5. The memory device according to claim 1, wherein an included angle between a sidewall of the upper portion and the bottom surface of the upper portion of each of the isolation structures is in a range of 40 degrees to 87 degrees.

6. The memory device according to claim 1, wherein a material of the cap layer comprises a high dielectric constant material or a combination of the high dielectric constant material and a low dielectric constant material.

7. A memory device, comprising:
a substrate;
a plurality of tunneling dielectric layers disposed on the substrate;
a plurality of isolation structures each comprising an upper portion and a lower portion, wherein the lower portions of the isolation structures are located in the substrate and arranged alternately with the tunneling dielectric layers in a first direction, and the upper portions of the isolation structures are disposed on the lower portions; and
a plurality of cap layers disposed on the upper portions of the isolation structures, wherein a top surface of each of the cap layers is a planar surface.

8. The memory device according to claim 7, wherein a top surface of the upper portion of each of the isolation structures is higher than a top surface of each of the tunneling dielectric layers, and a bottom surface of the upper portion of each of the isolation structures is level with the top surface of each of the tunneling dielectric layers.

9. The memory device according to claim 7, wherein a structure of the upper portion of each of the isolation structures and the cap layer on the upper portion satisfies the following (1) and (2):
$$\begin{matrix}b \leq c - 2 \times T 1 < c , and & ( 1 ) \\ b \geq \frac{c - 2 \times T 1}{3} , & ( 2 )\end{matrix}$$
wherein T1 represents a thickness of the cap layer, b represents a width of the top surface of each of the cap layers, and c represents a width of the bottom surface of the upper portion of each of the isolation structures.

10. The memory device according to claim 7, wherein an included angle between a sidewall of the upper portion and the bottom surface of the upper portion of each of the isolation structures is in a range of 40 degrees to 87 degrees.

11-20. (canceled)

21. The memory device according to claim 7, wherein the substrate further comprises a plurality of first regions and a plurality of second regions, in which the first regions and the second regions extend in a first direction and are arranged alternately in a second direction; and
the tunneling dielectric layers extend in the second direction across the first regions and the second regions.

22. The memory device according to claim 21, further comprising:
a plurality of first conductor layers disposed on the tunneling dielectric layers of the second regions;
a dielectric layer covering the first conductor layers; and
a second conductor layer disposed on the dielectric layer and comprising a body portion and a plurality of extending portions, wherein the extending portions and the first conductor layers are arranged alternately in the first direction.

23. The memory device according to claim 21, wherein a material of the cap layer comprises a high dielectric constant material or a combination of the high dielectric constant material and a low dielectric constant material.
